(19) United States
(12) Patent Application Publication
(10) Pub. No.: US 2024/0021569 A1
(43) Pub. Date: Jan. 18, 2024

(54) SEMICONDUCTOR MODULE AND METHOD FOR MANUFACTURING SEMICONDUCTOR MODULE

(71) Applicant: FUJI ELECTRIC CO., LTD., Kawasaki-shi (JP)

(72) Inventors: Yoko NAKAMURA, Kawasaki-shi (JP); Akihiko IWAYA, Kawasaki-shi (JP); Mai SAITO, Kawasaki-shi (JP); Tsubasa WATAKABE, Kawasaki-shi (JP)

(73) Assignee: FUJI ELECTRIC CO., LTD., Kawasaki-shi (JP)

(21) Appl. No.: 18/477,635

(22) Filed: Sep. 29, 2023

Related U.S. Application Data
(63) Continuation of application No. PCT/JP2022/037802, filed on Oct. 11, 2022.

(30) Foreign Application Priority Data
Oct. 22, 2021 (JP) 2021-173308

(51) Int. Cl. H01L 23/00; H01L 23/373; H01L 23/31

(52) U.S. Cl. CPC H01L 24/40; H01L 23/3735; H01L 23/3107; H01L 24/35; H01L 2224/40175; H01L 2224/4007; H01L 2224/352

(57) ABSTRACT

A semiconductor module includes a stacked substrate includes an insulating plate and first and second circuit boards arranged on the insulating plate, a semiconductor element arranged on the first circuit board, and a metal wiring board having a first bonding portion bonded to an upper surface of the semiconductor element via a first bonding material. The first bonding portion includes a first plate-shaped portion that has at a lower surface thereof, a boss protruding toward the semiconductor element, and at an upper surface thereof, a first recess at a position corresponding to a position immediately above the boss and multiple second recesses. At the upper surface of the first plate-shaped portion, each of the second recesses has an opening area smaller than an opening area of the first recess.

### CROSS REFERENCE TO RELATED APPLICATIONS

This is a continuation application of International Application PCT/JP2022/037802 filed on Oct. 11, 2022 which claims priority from a Japanese Patent Application No. 2021-173308 filed on Oct. 22, 2021, the contents of which are incorporated herein by reference.

### BACKGROUND

### Technical Field

The present invention relates to a semiconductor module and a method for manufacturing the semiconductor module.

### Related Art

A semiconductor module has a circuit board on which a semiconductor element such as an insulated gate bipolar transistor (IGBT), a power metal oxide semiconductor field effect transistor (power MOSFET), and a free wheeling diode (FWD) is provided, and is used in an inverter device and the like.

In this type of semiconductor module, a semiconductor element is arranged on an insulating substrate (which may be referred to as a stacked substrate), and a metal wiring board for wiring (which may be referred to as a lead frame) is arranged on an upper surface electrode of the semiconductor element in, for example, Japanese Patent Laid-Open No. 2018-088448, Japanese Patent Laid-Open No. 2016-139635, and Japanese Patent Laid-Open No. 2015-176871. The metal wiring board is formed into a predetermined shape by, for example, press working for a metal plate. One end of the metal wiring board is electrically bonded to the upper surface electrode via a bonding material such as solder.

### SUMMARY

In this type of semiconductor module, the power semiconductor element generates heat due to switching operation. In the structure in which the metal wiring board is solder-bonded to the surface of the power semiconductor element as described above, distortion may occur in the bonding portion due to a fluctuation of internal stress generated with temperature change. In addition, it is assumed that the plate-shaped bonding portion facing the upper surface electrode of the semiconductor element will be inclined during solder bonding, partially reducing the solder thickness.

The present invention has been made in view of such aspects, and an object of the present invention is to provide a semiconductor module capable of improving bonding strength between the semiconductor element and the metal wiring board while securing the thickness of the bonding material.

A semiconductor module according to one aspect of the present invention includes: a stacked substrate in which a plurality of circuit boards are arranged on an upper surface of an insulating plate; a semiconductor element arranged on an upper surface of at least one of the circuit boards; and a metal wiring board arranged on an upper surface of the semiconductor element, in which the metal wiring board has a first bonding portion bonded to the upper surface of the semiconductor element via a first bonding material, and the first bonding portion includes a plate-shaped portion having an upper surface and a lower surface, and comprises a boss formed on the lower surface of the plate-shaped portion and protruding toward the semiconductor element, a first recess formed at a position corresponding to a position immediately above the boss on the upper surface of the plate-shaped portion, and a plurality of second recesses formed on the upper surface and smaller than the first recess.

In addition, a method for manufacturing a semiconductor module according to one aspect of the present invention is a method for manufacturing the semiconductor module described above and includes a step of pressing and forming the boss and the first recess in the process of manufacturing the metal wiring board.

According to the present invention, it is possible to improve the bonding strength between the semiconductor element and the metal wiring board while securing the thickness of the bonding material.

### BRIEF DESCRIPTION OF DRAWINGS

FIG. 1 is a schematic view of a semiconductor device according to a present embodiment as viewed from above;

FIG. 2 is a cross-sectional view of the semiconductor device illustrated in FIG. 1 taken along line A-A;

FIG. 3 is an enlarged view of a metal wiring board according to the present embodiment;

FIG. 4 is a plan view of the metal wiring board illustrated in FIG. 3 as viewed in a direction of arrow B;

FIG. 5 is an enlarged view of a portion C of the metal wiring board illustrated in FIG. 3;

FIG. 6 is a plan view of the metal wiring board illustrated in FIG. 4 as viewed in a direction of arrow D;

FIGS. 7A and 7B are schematic views illustrating modifications of a recess formed on a surface of the metal wiring board;

FIGS. 8A to 8C are schematic views illustrating other arrangement examples of the recess formed on the surface of the metal wiring board;

FIGS. 9A and 9B are schematic views illustrating variations of a boss and recess formed on the metal wiring board;

FIG. 10 is a plan view illustrating a specific example of a semiconductor module to which the metal wiring board according to the present embodiment is applied;

FIG. 11 is an equivalent circuit diagram of the semiconductor device according to the present embodiment; and

FIG. 12 is a flowchart illustrating an example of a method for manufacturing the semiconductor module according to the present embodiment.

### DETAILED DESCRIPTION

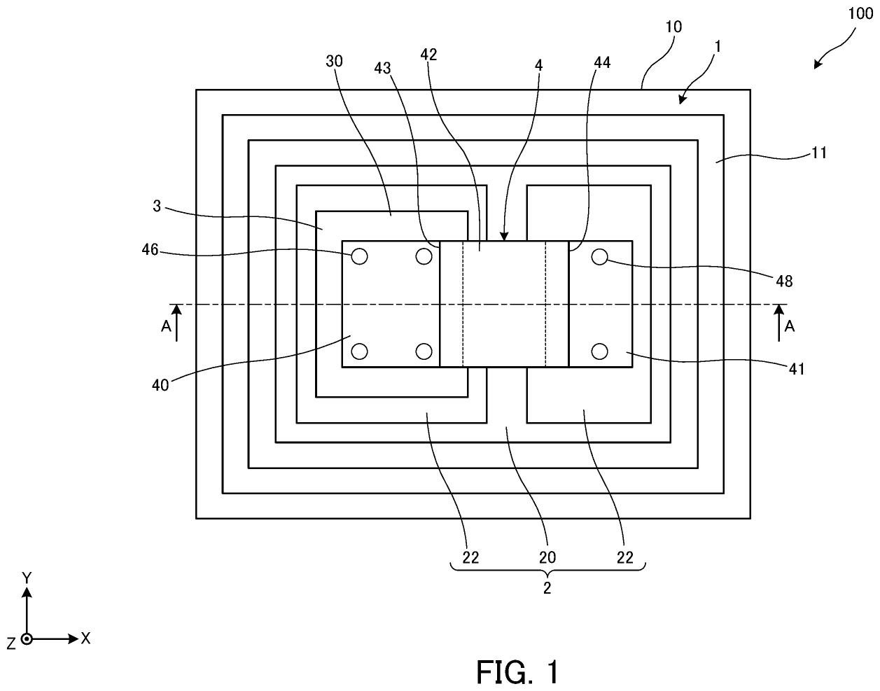

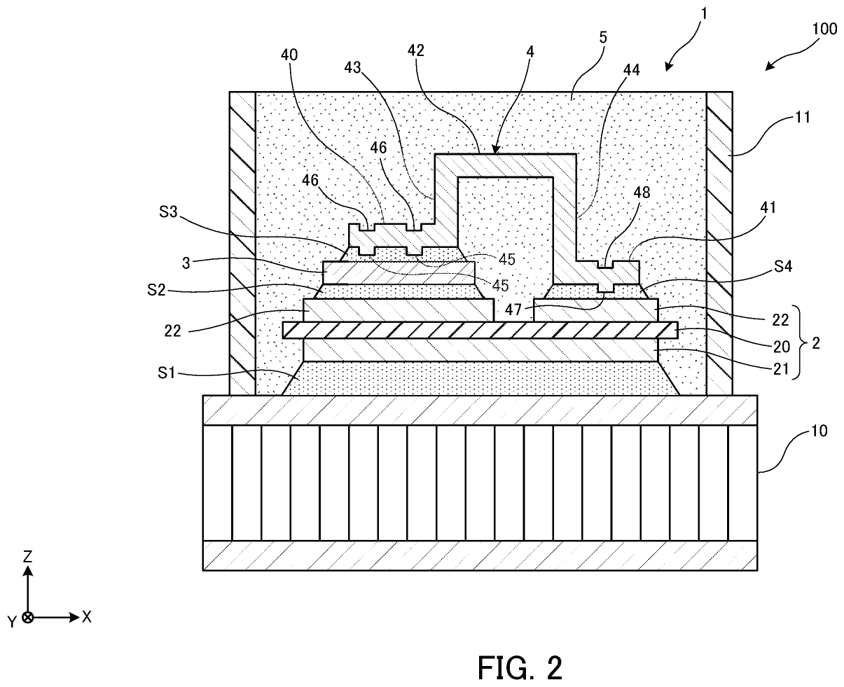

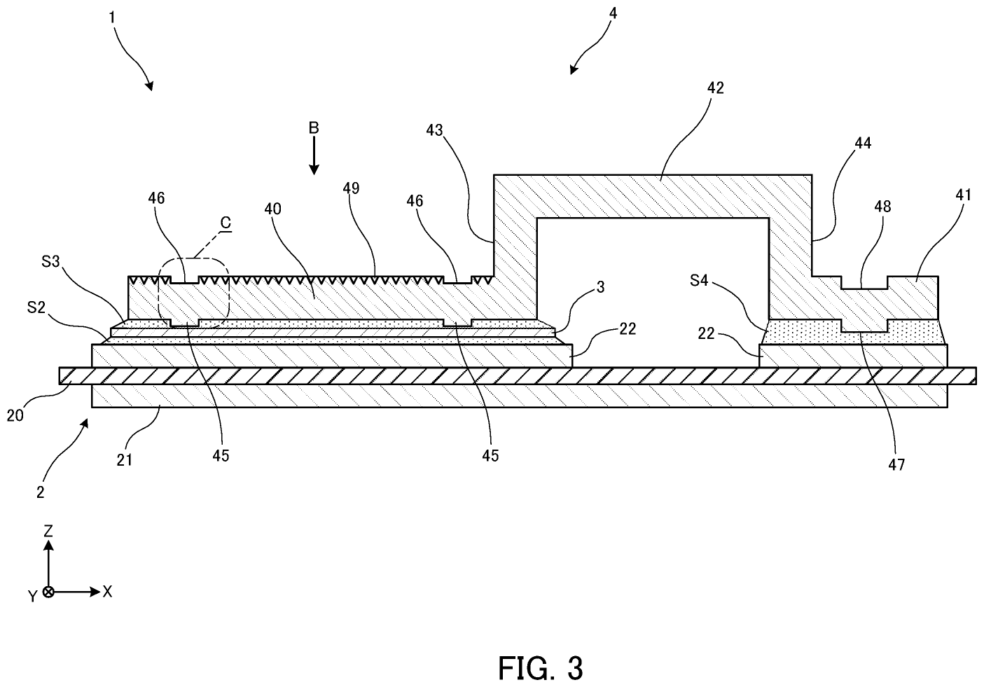

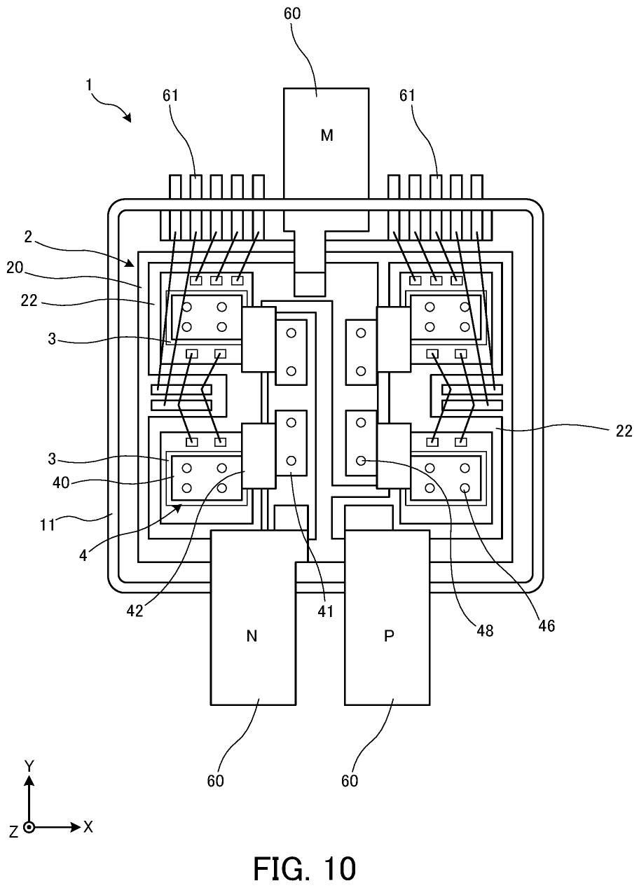

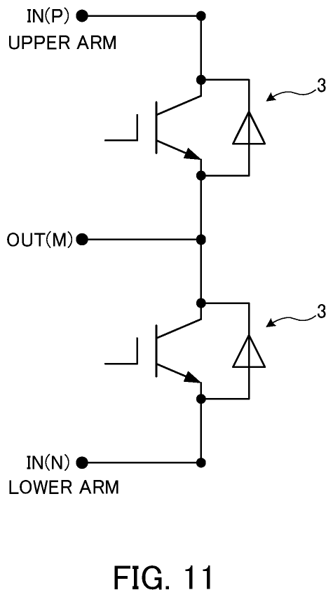

Hereinafter, a semiconductor module and a semiconductor device to which the present invention can be applied will be described. FIG. 1 is a schematic view of a semiconductor device according to a present embodiment as viewed from above. FIG. 2 is a cross-sectional view of the semiconductor device illustrated in FIG. 1 taken along line A-A. FIG. 3 is an enlarged view of a metal wiring board according to the present embodiment. FIG. 10 is a plan view illustrating a specific example of a semiconductor module to which the metal wiring board according to the present embodiment is applied. FIG. 11 is an equivalent circuit diagram of the semiconductor device according to the present embodiment. Here, the configuration is such that anti-parallel circuits of an IGBT and an FWD are connected in series as a semiconductor element 3.

In the following drawings, a longitudinal direction of the semiconductor module (a cooler) is defined as an X direction, a lateral direction of the semiconductor module (the cooler) is defined as a Y direction, and a height direction (a direction of the thickness of the substrate) is defined as a Z direction. The longitudinal direction of the semiconductor module indicates a direction in which the plurality of circuit boards are arrayed. X, Y, and Z axes illustrated are orthogonal to each other and form a right-handed system. In some cases, the X direction may be referred to as a left-right direction, the Y direction may be referred to as a front-rear direction, and the Z direction may be referred to as an up-down direction. These directions (front-rear, left-right, and up-down directions) are terms used for convenience of description, and a correspondence relationship with the XYZ directions, respectively, may change depending on an attachment posture of the semiconductor module. For example, a heat dissipation surface side (cooler side) of the semiconductor module is referred to as a lower surface side, and the opposite side is referred to as an upper surface side. In the present specification, the term “in plan view” means a case where an upper surface or a lower surface of the semiconductor module is viewed from the Z direction. In addition, the aspect ratio and the size relationship between members in the drawings are indicated in schematic views, and thus do not necessarily coincide between the drawings. For convenience of description, it is also assumed that the size relationship between the members is exaggerated.

A semiconductor device 100 according to the present embodiment is applied to, for example, a power conversion device such as an inverter of an industrial or in-vehicle motor. As illustrated in FIGS. 1 and 2, the semiconductor device 100 is configured by arranging a semiconductor module 1 on an upper surface of a cooler 10. Note that the cooler 10 has an any configuration with respect to the semiconductor module 1.

The cooler 10 releases heat of the semiconductor module 1 to the outside, and has a rectangular parallelepiped shape as a whole. Although not particularly illustrated, the cooler 10 is configured by providing a plurality of fins on a lower surface side of a base plate and housing these fins in a water jacket. Note that the cooler 10 is not limited thereto and can be appropriately changed.

The semiconductor module 1 is configured by arranging a stacked substrate 2, the semiconductor element 3, a metal wiring board 4, and the like in a case 11.

The stacked substrate 2 is configured as, for example, a direct copper bonding (DCB) substrate, an active metal brazing (AMB) substrate, or a metal base substrate. The stacked substrate 2 is configured by stacking an insulating plate 20, a heat sink 21, and a plurality of circuit boards 22, and is formed into a rectangular shape as a whole in plan view.

Specifically, the insulating plate 20 is formed into a plate-shaped body having an upper surface and a lower surface, and has a rectangular shape elongated in the X direction in plan view. The insulating plate 20 may be formed of, for example, a ceramic material such as aluminum oxide (Al₂O₃), aluminum nitride (AlN), silicon nitride (Si₃N₄), and aluminum oxide (Al₂O₃) and zirconium oxide (ZrO₂).

In addition, the insulating plate 20 may be formed of, for example, a thermosetting resin such as an epoxy resin or a polyimide resin, or a composite material using glass or a ceramic material as a filler in the thermosetting resin. The insulating plate 20 preferably has flexibility and may be formed of, for example, a material containing a thermosetting resin. The insulating plate 20 may be referred to as an insulating layer or an insulating film.

The heat sink 21 has a predetermined thickness in the Z direction and has a rectangular shape elongated in the Y direction in plan view. The heat sink 21 is formed of, for example, a metal plate having good thermal conductivity such as copper or aluminum. The heat sink 21 is arranged on the lower surface of the insulating plate 20. The lower surface of the heat sink 21 is a surface to be attached to the cooler 10, a device to which the semiconductor module 1 is attached, and also functions as a heat dissipation surface (heat dissipation region) for releasing heat of the semiconductor module 1. The heat sink 21 is bonded to the upper surface of the cooler 10 via a bonding material S1 such as solder. The heat sink 21 may be arranged on the upper surface of the cooler 10 via a thermal conductive material such as thermal grease or thermal compound.

Each of the plurality of circuit boards 22 has a predetermined thickness and is arranged on the upper surface of the insulating plate 20. Each of the circuit boards 22 is formed into an electrically independent island shape. For example, the circuit board 22 has a rectangular shape in plan view, and is arranged side by side in the X direction on the insulating plate 20. Note that the number of the circuit boards 22 is not limited to two as illustrated in FIG. 1, and can be changed as appropriate. As illustrated in FIG. 10, three or more circuit boards 22 may be arranged on the insulating plate 20. In addition, the shape, arrangement location, and the like of the circuit board 22 are not limited thereto and can be changed as appropriate. These circuit boards 22 are formed of, for example, a metal plate having good thermal conductivity such as copper or aluminum. The circuit board 22 may be referred to as a circuit layer or a circuit pattern.

The semiconductor element 3 is arranged on an upper surface of the predetermined circuit board (first circuit board) 22 (circuit board 22 on the negative side in the X direction) via the bonding material S2 such as solder. The semiconductor element 3 is formed of a semiconductor substrate such as silicon (Si) or silicon carbide (SiC) in a rectangular shape in plan view. The semiconductor element 3 may be a power semiconductor element. For the semiconductor element 3, a switching element such as an insulated gate bipolar transistor (IGBT) and a power metal oxide semiconductor field effect transistor (power MOSFET), and a diode such as a free wheeling diode (FWD) are used.

In the present embodiment, the semiconductor element 3 includes, for example, a reverse conducting (RC)-insulated gate bipolar transistor (IGBT) element in which the functions of an IGBT element and a free wheeling diode (FWD) element are integrated.

Note that the semiconductor element 3 is not limited thereto, and may be configured by combining the above-described switching element, diode, and the like. For example, the IGBT element and the FWD element may be configured separately. A reverse blocking (RB)-IGBT or the like having a sufficient withstand voltage against a reverse bias may be used as the semiconductor element 3. In addition, the shape, number, location, and the like of the semiconductor element 3 to be arranged can be changed as appropriate.

In addition, electrodes (not illustrated) are formed on an upper surface and a lower surface of the semiconductor element 3, respectively. For example, the electrode on the upper surface side (upper surface electrode) is configured as an emitter electrode (source electrode) or a gate electrode, and the electrode on the lower surface side (lower surface electrode) is configured as a collector electrode (drain electrode).

Note that the semiconductor element 3 in the present embodiment is a so-called vertical switching element in which the functional element as described above is formed on a semiconductor substrate, but is not limited thereto, and may be a horizontal switching element.

The metal wiring board 4 is arranged on the upper surface of the semiconductor element 3. The metal wiring board 4 is configured as a plate-shaped body having an upper surface and a lower surface, and is formed of, for example, a metal material such as a copper material, a copper alloy-based material, an aluminum alloy-based material, or an iron alloy-based material. The metal wiring board 4 is formed into a predetermined shape by, for example, press working. Note that the shape of the metal wiring board 4 described below is merely an example, and can be changed as appropriate. In addition, the metal wiring board may be referred to as a lead frame.

The metal wiring board 4 according to the present embodiment is an elongated body extending in the X direction so as to straddle the plurality of circuit boards 22 in plan view, and has a crank shape that is bent a plurality of times in side view. Specifically, as illustrated in FIGS. 2 and 3, the metal wiring board 4 is configured by including a first bonding portion 40 bonded to the upper surface (the upper electrode) of the semiconductor element 3 via a bonding material S3 (a first bonding material), a second bonding portion 41 bonded to the upper surface of the circuit board (second circuit board) 22 on the positive side in the X direction via a bonding material S4 (a second bonding material), and a connecting portion 42 connecting the first bonding portion 40 and the second bonding portion 41.

The width of the metal wiring board 4 in the Y direction is uniform from the first bonding portion 40 to the second bonding portion 41. In addition, the first bonding portion 40, the second bonding portion 41, and the connecting portion 42 are arranged in a line along the X direction in plan view. Note that the width of the metal wiring board 4 in the Y direction is not necessarily uniform from the first bonding portion 40 to the second bonding portion 41, and each portion may have a different width as illustrated in FIG. 10. In addition, the first bonding portion 40, the second bonding portion 41, and the connecting portion 42 are not necessarily arranged in a line, and may be arranged so as to be obliquely shifted from each other as illustrated in FIG. 10.

The first bonding portion 40 is formed into a rectangular shape smaller than the outer shape of the semiconductor element 3 in plan view, and includes a plate-shaped portion (first plate-shaped portion) having an upper surface and a lower surface. A first bent portion 43 that is bent at a substantially right angle and rises upward is formed at an end portion of the first bonding portion 40 on the positive side in the X direction (the connecting portion 42 side). One end (the left end) of the connecting portion 42 is connected to the upper end of the first bent portion 43. Although details will be described later, a plurality of bosses 45 protruding toward the semiconductor element 3 are formed on a lower surface of the first bonding portion 40. In addition, on the upper surface of the first bonding portion 40, a plurality of first recesses 46 are formed at positions corresponding to the positions immediately above the bosses 45.

The second bonding portion 41 is formed into a rectangular shape smaller than the outer shape of the circuit board 22 in plan view, and includes a plate-shaped portion (second plate-shaped portion) having an upper surface and a lower surface. A second bent portion 44 that is bent at a substantially right angle and rises upward is formed at an end portion of the second bonding portion 41 on the negative side in the X direction (the connecting portion 42 side). The other end (the right end) of the connecting portion 42 is connected to the upper end of the second bent portion 44. Although details will be described later, a plurality of bosses 47 protruding toward the circuit board 22 are formed on a lower surface of the second bonding portion 41. In addition, on the upper surface of the second bonding portion 41, a third recess 48 is formed at a position corresponding to a position immediately above the boss 47.

The connecting portion 42 extends in the horizontal direction, and as described above, one end thereof is connected to the first bent portion 43 and the other end thereof is connected to the second bent portion 44.

The length of the first bent portion 43 in the Z direction is shorter than that of the second bent portion 44 by the thickness of the semiconductor element 3. That is, the first bonding portion 40 and the second bonding portion 41 are provided at a position with different heights. More specifically, the first bonding portion 40 is provided at a position higher than the second bonding portion 41.

Note that the shape, number, arrangement location, and the like of the metal wiring board 4 described above are merely examples, and are not limited thereto and can be changed as appropriate. Although details will be described later, a plurality of (for example, four) metal wiring boards 4 may be arranged on one semiconductor module as illustrated in FIG. 10. In the present embodiment, the above-described semiconductor element 3 and metal wiring board 4, and a main terminal and the like to be described later form, for example, an inverter circuit illustrated in FIG. 11.

The periphery of the stacked substrate 2, the semiconductor element 3, and the metal wiring board 4 is surrounded by a case 11. The case 11 has a quadrangular annular tubular shape or a frame shape in plan view, and is formed of, for example, a synthetic resin. The case 11 may be formed of, for example, a thermosetting resin such as an epoxy resin and silicone rubber. The lower end of the case 11 is bonded to the upper surface of the cooler 10 via an adhesive (not illustrated), and the upper end extends to a position sufficiently higher than the upper surface of the metal wiring board 4. Thus, the case 11 surrounds the periphery of the stacked substrate 2, the semiconductor element 3, and the metal wiring board 4, and defines a space for housing the stacked substrate 2, the semiconductor element 3, and the metal wiring board 4.

The internal space defined by the case 11 is filled with a sealing resin 5. The case 11 may be filled with the sealing resin 5 until its upper surface reaches the upper end of the case 11. Thus, the stacked substrate 2, the semiconductor element 3, and the metal wiring board 4 are sealed. The entire metal wiring board 4 is covered with the sealing resin 5.

The sealing resin 5 may be configured as, for example, a thermosetting resin. The sealing resin 5 preferably contains at least one of epoxy, silicone, urethane, polyimide, polyamide, and polyamide-imide. For example, an epoxy resin mixed with a filler is suitable for the sealing resin 5 from the viewpoint of insulation, heat resistance, and heat dissipation properties.

As in the specific example illustrated in FIG. 10, the case 11 may be provided with a plurality of main terminals 60 for main current and a plurality of control terminals 61 for control. The main terminal 60 is formed into a plate-shaped elongated body and is embedded in a side wall of the case 11. In FIG. 10, two main terminals 60 constituting an N terminal and P terminal are arranged side by side in the X direction on the side wall of the case 11 located on the negative side in the Y direction. A main terminal 60 constituting an M terminal is arranged on the side wall of the case 11 located on the positive side in the Y direction.

As described above, in the present embodiment, the semiconductor element 3, the metal wiring board 4, the main terminal 60, and the like form, for example, the inverter circuit illustrated in FIG. 11. These main terminals 60 (N terminal, P terminal, M terminal) correspond to IN (N) (which may be referred to as a low potential-side input terminal or a negative electrode terminal), IN (P) (which may be referred to as a high potential-side input terminal or a positive electrode terminal), and OUT (M) (which may be referred to as an output terminal or an intermediate terminal) in FIG. 11, respectively.

In addition, each control terminal 61 is formed into a plate-shaped elongated body and is embedded in the side wall of the case 11 located on the positive side in the Y direction. Each control terminal 61 is electrically connected to a predetermined control electrode of the semiconductor element 3 via a wiring member such as a bonding wire. These main terminal 60 and the control terminal 61 are formed of a metal material such as a copper material, a copper alloy-based material, an aluminum alloy-based material, or an iron alloy-based material, and have predetermined electrical conductivity and predetermined mechanical strength. The shapes, numbers, arrangement locations, and the like of the main terminal 60 and the control terminal 61 are not limited thereto, and can be changed as appropriate.

By the way, when the semiconductor module is subjected to a power cycle test and operated until failure occurs, many of the failures are due to electrode failure of the semiconductor element. As factors that can cause an early failure of the semiconductor module, for example, the following events are considered.

(1) When the thickness of the bonding material between the semiconductor element and the metal wiring board is reduced, electrode distortion increases, leading to a decrease in tolerance.

(2) The thermal stress causes peeling from the interface between the bonding material, which is between the semiconductor element and the metal wiring board, and the sealing resin. The peeling progresses along the interface between the metal wiring board and the sealing resin. When the thermal deformation of the metal wiring board increases due to the progress of the peeling, the electrode distortion increases, leading to a decrease in tolerance.

Therefore, in order to improve the tolerance of the semiconductor module, it is necessary to:
(i) secure the thickness of the bonding material between the semiconductor element and the metal wiring board; and
(ii) suppress the peeling of the interface between the metal wiring board and the sealing resin.

Regarding (i), conventionally, in the bonding process (soldering process), the posture of the metal wiring board may be inclined with respect to the upper surface electrode of the semiconductor element due to the shape, the center of gravity, and the like of the metal wiring board. As a result, the thickness of the bonding material (solder) immediately below the metal wiring board is uneven, thus locally creating an area where the thickness is not secured. That is, it is difficult to secure the thickness of the bonding material between the semiconductor element and the metal wiring board.

Regarding (ii), as a method for reducing peeling, it is conceivable, for example, to increase the surface area of the metal wiring board to improve adhesion (anchor effect) between the metal wiring board and the sealing resin. Examples of a method for increasing the surface area of the metal wiring board include forming an uneven shape on the surface of the metal wiring board. However, when the lower surface of the metal wiring board (the surface facing the semiconductor element) has an uneven shape, voids and sink marks are likely to occur in the bonding material. As a result, the mounting quality of the metal wiring board may be affected.

Examples of a method for roughening the surface of the metal wiring board include laser processing and a wet method using a chemical solution. However, these methods not only cause an increase in cost, but also may cause voids and sink marks in the bonding material due to a roughened lower surface side of the metal wiring board. That is, it is difficult to roughen the surface of the metal wiring board without affecting the quality of the bonding material immediately below the metal wiring board.

Therefore, the present inventors have conceived the present invention in order to achieve both the above items (i) and (ii). Specifically, in the present embodiment, the first recesses 46 are formed by recessing the first bonding portion 40 of the metal wiring board 4 from the upper surface side, and the bosses 45 are formed to protrude from the lower surface side. On the upper surface of the first bonding portion 40, a plurality of second recesses 49 are formed. Further, at the upper surface of the first bonding portion 40, an opening area of each second recess 49 is smaller than an opening area of each first recess 46. The bosses 45, the first recesses 46, and the second recess 49 are formed by press working.

Four bosses 45 are arranged at positions close to the four corners of the rectangular first bonding portion 40 in plan view. By forming the plurality of bosses 45 in this manner, the first bonding portion 40 is not inclined with respect to the upper surface of semiconductor element 3 in the bonding process of metal wiring board 4. Thus, the posture of the metal wiring board 4 (the first bonding portion 40) can be stabilized.

In particular, by providing the bosses 45 on the lower surface of the metal wiring board 4, a gap can be secured between the first bonding portion 40 and the semiconductor element 3 by at least the height of the bosses 45. By filling the gap with the bonding material S3, the thickness of the bonding material S3 can be secured.

The upper surface of the first bonding portion 40 is roughened by forming the plurality of second recesses 49. As a result, the surface area of the upper surface of the first bonding portion 40 increases, and the adhesion (anchor effect) between the upper surface of the first bonding portion 40 and the sealing resin can be improved. Thus, the progress of the peeling of the upper surface of the metal wiring board 4 due to thermal stress can be suppressed at a position above the semiconductor element 3.

In addition, since the configuration for realizing these effects can be obtained by cheaper press working, there is a cost advantage as compared with the conventional surface roughening method that uses laser processing or a wet method with a chemical solution. Thus, according to the present embodiment, it is possible to improve the bonding strength between the semiconductor element and the metal wiring board while securing the thickness of the bonding material.

In addition, the bosses 47 protruding toward the circuit board 22 are also formed on the back surface side of the second bonding portion 41. As a result, a gap can be secured between the second bonding portion 41 and the circuit board 22 by at least the height of the bosses 47. By filling the gap with the bonding material S4, the thickness of the bonding material S4 can be secured.

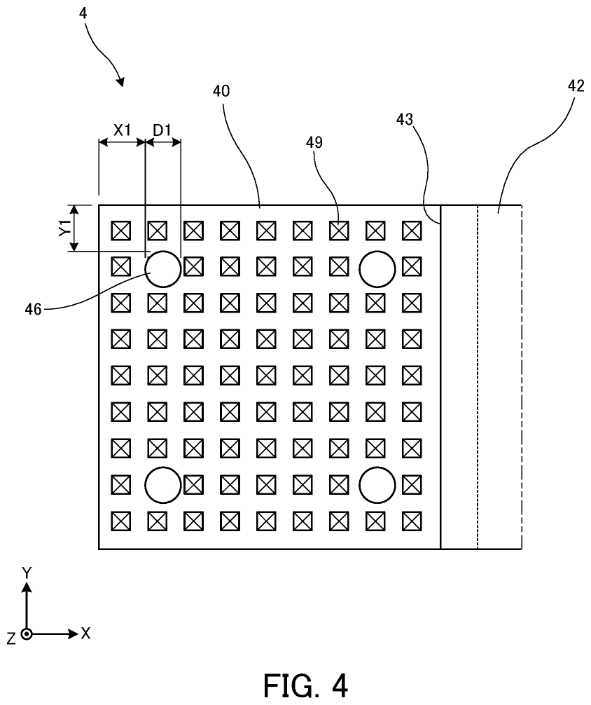

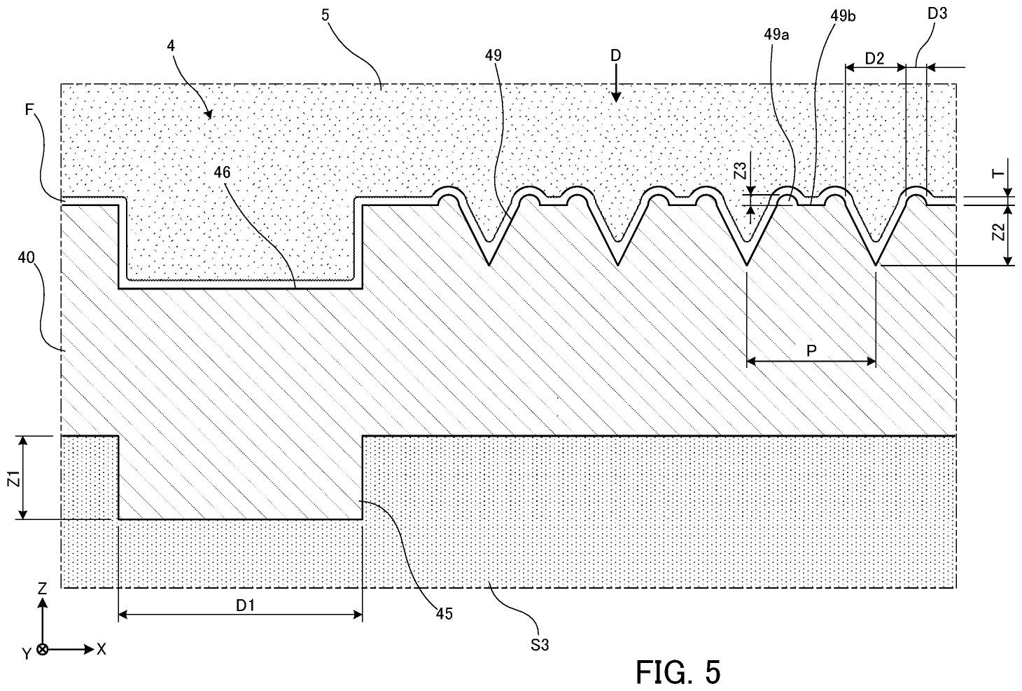

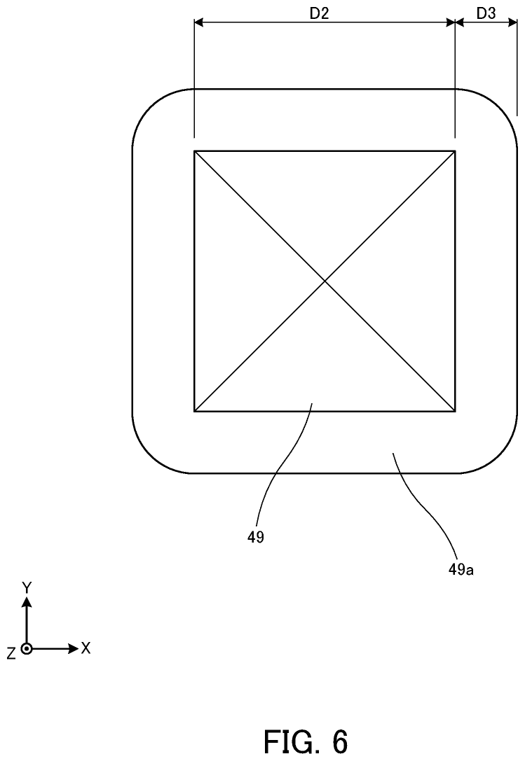

Next, a detailed structure of the metal wiring board 4 according to the present embodiment will be described with reference to FIGS. 1 to 6. FIG. 4 is a plan view of the metal wiring board illustrated in FIG. 3 as viewed in a direction of arrow B. FIG. 5 is an enlarged view of a portion C of the metal wiring board illustrated in FIG. 3. FIG. 6 is a plan view of the metal wiring board illustrated in FIG. 5 as viewed in a direction of arrow D.

As illustrated in FIGS. 1 to 6, the plurality of bosses 45 are provided on the lower surface of the first bonding portion 40. In the present embodiment, a total of four bosses 45 are provided, two bosses in the X direction and two bosses in the Y direction. The four bosses 45 are arranged at positions corresponding to the four corners of the first bonding portion 40 along the outer peripheral edge of the first bonding portion 40. For example, as illustrated in FIG. 4, a predetermined boss 45 may be provided at a position separated from one corner of the first bonding portion 40 by a distance X1 in the X direction and a distance Y1 in the Y direction. The distance X1 and the distance Y1 may be 0.25 mm to 2.5 mm, preferably 0.5 mm to 2.0 mm. The distance X1 may be the same as the distance Y1.

The boss 45 has, for example, a cylindrical shape with an outer diameter D1. In addition, the boss 45 protrudes from the lower surface of the first bonding portion 40 toward the semiconductor element 3 at a protrusion height Z1. The side surface (cylindrical surface) of the boss 45 may be perpendicular to the lower surface of the first bonding portion 40. The outer diameter D1 of the boss 45 is, for example, 0.4 mm to 1.5 mm, and may be preferably 0.6 mm to 1.2 mm. In addition, the protrusion height Z1 of the boss 45 may be 50 μm or more and 300 μm or less, and preferably 100 μm to 200 μm. Too large a protrusion height Z1 may cause voids to be generated in the bonding material S3, while too small a protrusion height Z1 causes the bonding material S3 to become thin, making it impossible to secure a sufficient thickness.

In addition, on the upper surface of the first bonding portion 40, the first recess 46 is formed at a position corresponding to a position immediately above the boss 45. The first recess 46 may have a complementary shape to the boss 45, and may have, for example, a cylindrical shape having the same diameter (an outer diameter D1) as that of the boss 45. The inner diameter of the first recess 46 may be smaller than the outer diameter D1 of the boss 45. The depth of the first recess 46 may be Z1 that is the same as the protrusion height of the boss 45, or may be smaller than Z1. The outer diameter D1 of the first recess 46 is, for example, 0.4 mm to 1.5 mm, and may be preferably 0.6 mm to 1.2 mm. In addition, the depth of the first recess 46 may be 50 μm or more and 300 μm or less, and preferably 100 μm to 200 μm.

In addition, a plurality of bosses 47 (second bosses) are provided on the lower surface of the second bonding portion 41. In the present embodiment, two bosses 47 are provided side by side in the Y direction. The shape of the boss 47 may be the same as or different from the boss 45 described above.

In addition, on the upper surface of the second bonding portion 41, the third recess 48 is formed at a position corresponding to a position immediately above the boss 47. The third recess 48 may have a complementary shape to the boss 47, and may have, for example, a cylindrical shape having the same diameter as that of the boss 47. In addition, the third recess 48 may have the same shape and size as those of the first recess 46.

The shapes, arrangements, and numbers of the bosses 45 and 47, the first recess 46, and the third recess 48 described above are not limited thereto, and can be changed as appropriate. For example, the bosses 45 and 47 are not limited to a cylindrical shape, and may have a prismatic shape, a truncated cone shape tapered downward, or a hemispherical shape. Details will be described later.

In addition, a plurality of second recesses 49 are formed on the upper surface of the first bonding portion 40. The opening area of the second recess 49 is smaller than the opening area of the first recess 46 in plan view. For example, the second recess 49 may have a polygonal shape (Including triangles, quadrangles, pentagons, etc.) in plan view. In addition, the second recess 49 may have a square shape in plan view. A length D2 of one side of the square-shaped second recess 49 may be, for example, 50 μm or more and 600 μm or less, and is preferably 80 μm or more and 200 μm or less.

The second recess 49 may have a quadrangular pyramid shape. A depth Z2 of the second recess 49 may be 25% or more and 150% or less of the length D2 of one side of the second recess 49, and is preferably 50% or more and 110% or less. This shape allows the pressing die for forming the second recesses 49 to have a simple shape. For example, the depth Z2 of the second recess 49 may be smaller than the depth of the first recess 46. The depth Z2 of the second recess 49 may be 30% or more and 90% or less of the depth of the first recess 46, and is preferably 50% or more and 75% or less.

The plurality of second recesses 49 formed in this manner may be arranged side by side in a lattice shape with a predetermined pitch P at intervals in the X direction and the Y direction, for example. The predetermined pitch may be, for example, 100 μm or more and 900 μm or less, and is preferably 200 μm or more and 600 μm or less. Note that the plurality of second recesses 49 may be formed on the upper surface of the second bonding portion 41, or may be formed only on the upper surface of the first bonding portion 40. That is, the second recess 49 may not be formed in the connecting portion 42, the first bent portion 43, and the second bent portion 44, which constitute the portion other than the first bonding portion 40.

Since the semiconductor element 3 serving as a heat source is arranged immediately below the first bonding portion 40, it is possible to easily receive the influence of the anchor effect due to surface roughening of the first bonding portion 40. In addition, by roughening only the surface of the portion where the anchor effect is to be improved, it is not necessary to spend extra processing cost. That is, it can be said that the second bonding portion 41, the connecting portion 42, the first bent portion 43, and the second bent portion 44 have a smaller influence on the peeling of the sealing resin 5 than the first bonding portion 40. In this case, the surfaces of the second bonding portion 41, the connecting portion 42, the first bent portion 43, and the second bent portion 44 may be flat, and the surface roughness thereof may be equivalent to the surface roughness of the lower surface of the first bonding portion 40.

In addition, the portion of the lower surface of the first bonding portion 40 excluding the boss 45 is preferably a flat surface. That is, it is preferable that the second recess 49 is not formed on the lower surface of the first bonding portion 40. For example, the surface roughness of the lower surface of the first bonding portion 40 is preferably smaller than the surface roughness of the upper surface of the first bonding portion 40. When the lower surface of the first bonding portion 40 is flat, voids and sink marks are unlikely to be generated in the bonding material S3.

More specifically, the surface roughnesses of the upper surface and the lower surface of the first bonding portion 40 in the present embodiment were compared using a developed interfacial area ratio (Sdr). Here, the developed interfacial area ratio is a value measured in accordance with ISO 25178.

For example, on the lower surface of the first bonding portion 40, the developed interfacial area ratio is 0<Sdr< 0.2, and more preferably 0.02<Sdr<0.15. If the lower surface of the first bonding portion 40 is too rough, the wettability of solder worsens and thus voids and sink marks are likely to occur. On the other hand, on the upper surface of the first bonding portion 40, the developed interfacial area ratio is 0.10≤Sdr<1.0, and more preferably 0.2≤Sdr <1.0. If the developed interfacial area ratio is too small on the upper surface of the first bonding portion 40, peeling may not be sufficiently suppressed. In addition, if the developed interfacial area ratio is too large on the upper surface of the first bonding portion 40, warpage, undulation, and the like may occur during processing, leading to deformation.

In addition, the area of the second recess 49 in plan view may be 0.5% or more and 75% or less of the area of the boss 45 or the first recess 46, and is preferably 1.0% or more and 2.5% or less. Within this range, the surface area of the upper surface of the first bonding portion 40 can be effectively increased.

In addition, as illustrated in FIGS. 5 and 6, an annular protrusion 49a surrounding the second recess 49 may be formed on the upper surface of the first bonding portion 40. The annular protrusion 49a may have a quadrangular annular shape in plan view. A width D3 of the annular protrusion 49a is preferably, for example, 10 μm or more and 100 μm or less. The width D3 of the annular protrusion 49a is preferably 10% or more and 30% or less of the length D2 of one side of the square-shaped second recess 49. A height Z3 of the annular protrusion 49a is preferably 10% or more and 20% or less of the depth Z2 of the second recess 49. In addition, it is preferable that the plurality of adjacent annular protrusions 49a do not overlap each other. That is, it is preferable that a flat portion 49b is provided between at least two adjacent annular protrusions 49a. The flat portion 49b is continuous with the adjacent annular protrusion 49a. By forming such an annular protrusion 49a, the surface area of the upper surface of the first bonding portion 40 is further enlarged, thus further improving the anchor effect.

The upper surface of the first bonding portion 40 may be covered with the sealing resin 5. In this case, it is preferable that the sealing resin 5 enters the first recesses 46 and the second recesses 49. As a result, a further anchor effect can be expected.

In addition, as illustrated in FIG. 5, a coating film F may be interposed at the interface between the upper surface of the first bonding portion 40 and the sealing resin 5. The coating film increases the degree of chemical bonding with the sealing resin 5, and may be configured as, for example, a polyamide resin, a polyamide-imide resin, a polyether amide resin, or silica. The thickness of the coating film F is 0.1 μm or more and 20 μm or less, and more preferably 1 μm to 10 μm. In this case, it is preferable that the first recesses 46 and the second recesses 49 (inner side surfaces or inner bottom surfaces of them) are covered with the coating film F.

The second recess 49 may not be formed on the inner bottom surface and the inner side surface of the first recess 46. In this case, the inner surfaces (the inner bottom surface and the inner side surface described above) of the first recess 46 are preferably flat. In addition, the surface roughness of the inner surface of the first recess 46 is preferably smaller than the surface roughness of the upper surface of the first bonding portion 40 excluding the first recess 46. For example, the surface roughness of the inner surface of the first recess 46 may be equivalent to the surface roughness of the lower surface of the first bonding portion 40.

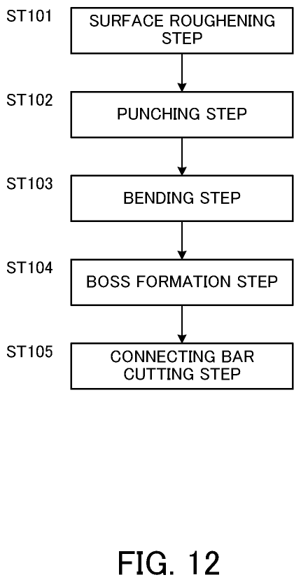

The manufacturing of the metal wiring board 4 configured as described above preferably includes the following steps. FIG. 12 is a flowchart illustrating an example of a method for manufacturing the semiconductor module (the metal wiring board) according to the present embodiment.

As illustrated in FIG. 12, the method for manufacturing the semiconductor module 1 according to the present embodiment includes following steps ST101 to ST105 in the process of manufacturing the metal wiring board 4.

In step ST101, a surface roughening step is performed first. In this step, a plurality of second recesses 49 are formed on the upper surface of the first bonding portion 40. Here, a metal plate is prepared as a material of the metal wiring board 4. Then, the metal plate is placed such that a lower surface of the metal plate corresponding to the lower surface of the metal wiring board 4 is in contact with a lower die having a flat surface. Then, an upper die having a plurality of predetermined protrusions is pressed against an upper surface of the metal plate corresponding to the upper surface of the metal wiring board 4. Thus, the plurality of second recesses 49 are formed in a predetermined region of the upper surface of the metal plate. The lower surface of the metal plate is formed flat. Surface roughening may be performed only on the region corresponding to the upper surface of the first bonding portion 40. Furthermore, a region corresponding to the first recess 46 may be excluded from the surface roughening.

In step ST102, a punching step is performed. In this step, the metal plate is punched into a predetermined shape. The term “predetermined shape” may refer to an outer shape in which a plurality of metal wiring boards 4 are partially connected by a connecting bar (not illustrated).

In step ST103, a bending step is performed. In this step, a predetermined portion of the metal wiring board 4 is bent and formed into a crank shape. Thus, the first bonding portion 40, the second bonding portion 41, the connecting portion 42, the first bent portion 43, and the second bent portion 44 are formed in the metal wiring board 4.

In step ST104, a boss formation step is performed. In this step, at a predetermined position of the metal wiring board 4 (for example, the first bonding portion 40), the first recesses 46 are formed on the upper surface of the metal wiring board 4 and the bosses 45 are formed on the lower surface of the metal wiring board 4. For example, the metal wiring board 4 is placed such that the lower surface of the metal wiring board 4 is in contact with the lower die having a plurality of recesses corresponding to the bosses 45. Then, the upper die having a plurality of protrusions corresponding to the first recesses 46 is pressed against the upper surface of the metal wiring board 4. Thus, the plurality of first recesses 46 are formed on the upper surface of the metal wiring board 4, and the plurality of bosses 45 are formed on the lower surface of the metal wiring board 4.

In step ST105, a connecting bar cutting step is performed. In this step, the connecting bars of the plurality of metal wiring boards 4 connected by the connecting bars are cut to be divided into individual metal wiring boards 4. This step may also be performed by press working using two upper and lower dies.

Steps ST101 to 105 described above are all realized by press working. Thus, it is possible to realize boss formation and surface roughening with an inexpensive configuration as compared with a case where laser processing or a chemical solution is used. Each step is merely an example, and the order of the steps can be changed as appropriate within a range not causing contradiction. In addition, other steps such as plating treatment and rust prevention treatment may be included.

As described above, according to the present embodiment, it is possible to improve the bonding strength between the semiconductor element and the metal wiring board while securing the thickness of the bonding material.

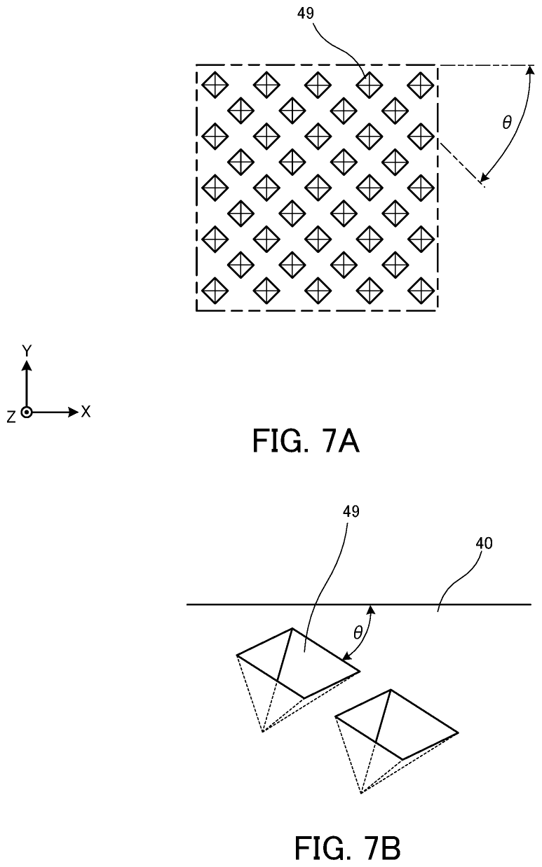

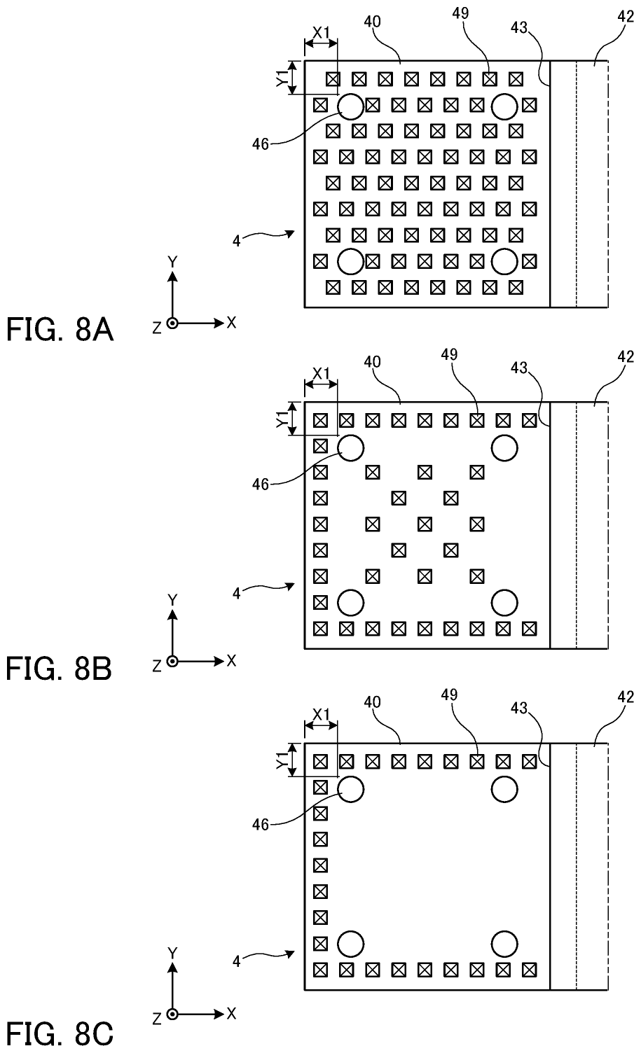

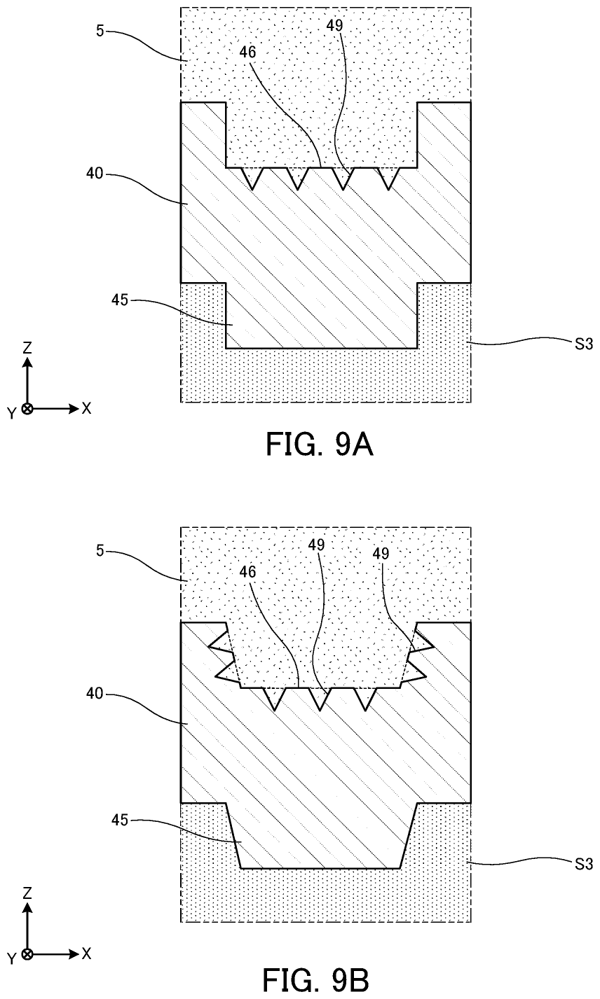

Next, modifications will be described with reference to FIGS. 7A and 7B to 9A and 9B. FIGS. 7A and 7B are schematic views illustrating a modification of the recess formed on the surface of the metal wiring board. FIG. 7A is a plan view, and FIG. 7B is a perspective view. FIGS. 8A to 8C are schematic views illustrating other arrangement examples of the recess formed on the surface of the metal wiring board. FIGS. 9A and 9B are schematic views illustrating a variation of the boss and recess formed on the metal wiring board. Note that, in the following modifications, the already described configurations are denoted by the same names and the same reference numerals, and the description thereof will be omitted as appropriate.

In the above embodiment, the case where one side of the second recess 49 having a polygonal shape in plan view is parallel to the X direction or the Y direction has been described, but the present invention is not limited to this configuration. For example, as illustrated in FIGS. 7A and 7B, one side of the second recess 49 may form a predetermined angle θ with respect to one side of the first bonding portion 40. The predetermined angle θ may be, for example, 45°.

In addition, in the above embodiment, the case where the plurality of second recesses 49 are arranged in a lattice shape with an equal pitch in plan view has been described, but the present invention is not limited to this configuration. For example, as illustrated in FIG. 8A, the plurality of second recesses may be arranged in a staggered manner. Here, the staggered arrangement refers to an arrangement in which a row of the second recesses 49 is formed by a plurality of second recesses 49 arrayed in a predetermined direction (for example, the X direction), and the row of the second recesses 49 is shifted by a half pitch (½ P) with respect to another adjacent row of the second recesses 49. In the staggered arrangement, the rows of the plurality of second recesses 49 are shifted with respect to each other by a half pitch.

As illustrated in FIG. 8B, the density of the plurality of second recesses 49 arranged on the outer peripheral side of the first recesses 46 may be larger than the density of the plurality of second recesses 49 arranged on the inner peripheral side of the first recess 46. The first recesses 46 are arranged at positions corresponding to the four corners of the first bonding portion 40. Each first recess 46 is provided at a position separated from one corner of the first bonding portion 40 by the distance X1 in the X direction and the distance Y1 in the Y direction. As described above, the distance X1 and the distance Y1 may be 0.25 mm to 2.5 mm, preferably 0.5 mm to 2.0 mm. The distance X1 may be the same as the distance Y1. In a region between the outer edge corresponding to the end of the first bonding portion 40 and the range of X1, the plurality of second recesses 49 may be arranged at a higher density than in a region on the first bent portion 43 side with respect to X1. In addition, in a region between the outer edge corresponding to the side edge of the first bonding portion 40 and the range of Y1, the plurality of second recesses 49 may be arranged at a higher density than in a region on the center side with respect to Y1. In the high density region, the number of the second recesses 49 per unit area may be twice or more as compared with the low density region.

As illustrated in FIG. 8C, the second recesses 49 may be arranged only on the outer peripheral side of the first recesses 46. Also in this case, the first recesses 46 may be arranged at the positions corresponding to the four corners of the first bonding portion 40. Each first recess 46 is provided at a position separated from one corner of the first bonding portion 40 by the distance X1 in the X direction and the distance Y1 in the Y direction. The plurality of second recesses 49 may be arranged in the region between the outer edge corresponding to the end of the first bonding portion 40 and the range of X1, and the region between the outer edge corresponding to the side edge of the first bonding portion 40 and the range of Y1.

In the above embodiment, the case where the second recesses 49 are not formed on the inner bottom surface and the inner side surface of the first recess 46 has been described. However, the present invention is not limited thereto, and for example, as illustrated in FIG. 9A, the second recesses 49 may be formed on the bottom surface of the first recess 46. In this case, it is preferable that the second recesses 49 formed on the bottom surface of the first recess 46 is also filled with a sealing resin. As a result, a further anchor effect can be expected.

As illustrated in FIG. 9B, the side surface of the boss 45 and the inner side surface of the first recess 46 may have a tapered shape whose diameter decreases downward. Furthermore, the second recesses 49 may also be formed on the inner side surface of the first recess 46. In this case, it is preferable that the second recesses 49 formed on the inner side surface of the first recess 46 is also filled with a sealing resin. As a result, a further anchor effect can be expected.

In the above-described embodiment, the number and arrangement location of the semiconductor elements 3 are not limited to the above-described configuration, and can be changed as appropriate.

In the above-described embodiment, the number and arrangement location of the circuit board are not limited to the above-described configuration, and can be changed as appropriate.

In the above-described embodiment, the stacked substrate 2 and the semiconductor element 3 are formed into the rectangular shape or the square shape in plan view, but the present invention is not limited to this configuration. These configurations may be formed in a polygonal shape other than the above.

The present embodiment and the modifications have been described, but as another embodiment, the above-described embodiment and the modifications may be wholly or partially combined.

The present embodiment is not limited to the above-described embodiment and modifications, and various changes, substitutions, and modifications may be made without departing from the spirit of the technical idea. When the technical idea can be realized in another manner by the progress of the technology or another derived technology, the technology may be implemented by using the manner. Thus, the claims cover all implementations that may be included within the scope of the technical idea.

The feature points in the above exemplary embodiments will be described below.

The semiconductor module according to the embodiment described above includes: the stacked substrate in which the plurality of circuit boards are arranged on the upper surface of the insulating plate; the semiconductor element arranged on the upper surface of at least one of the circuit boards; and the metal wiring board arranged on the upper surface of the semiconductor element, in which the metal wiring board has the first bonding portion bonded to the upper surface of the semiconductor element via the first bonding material, and the first bonding portion includes the plate-shaped portion having the upper surface and the lower surface, and comprises the boss formed on the lower surface of the plate-shaped portion and protruding toward the semiconductor element, the first recess formed at the position corresponding to a position immediately above the boss on the upper surface of the plate-shaped portion, and the plurality of second recesses formed on the upper surface and smaller than the first recess.

In the semiconductor module according to the above-described embodiment, a portion of the lower surface of the first bonding portion excluding the boss is a flat surface.

In the semiconductor module according to the above-described embodiment, the surface roughness of the lower surface of the first bonding portion is smaller than the surface roughness of the upper surface of the first bonding portion.

In the semiconductor module according to the above-described embodiment, an area of the second recess in plan view is 0.5% or more and 75% or less of an area of the boss or the first recess.

In the semiconductor module according to the above-described embodiment, the depth of the second recess is smaller than the depth of the first recess.

In the semiconductor module according to the above-described embodiment, the boss and the first recess have a circular shape in plan view, and the second recess has a polygonal shape in plan view.

In the semiconductor module according to the above-described embodiment, the annular protrusion surrounding the second recess is formed on the upper surface of the first bonding portion.

In the semiconductor module according to the above-described embodiment, a flat portion arranged between at least two adjacent annular protrusions is formed on the upper surface of the first bonding portion.

The semiconductor module according to the above-described embodiment further includes the sealing resin that seals the stacked substrate, the semiconductor element, and the metal wiring board, in which the sealing resin covers the upper surface of the first bonding portion and enters the first recess and the second recess.

The semiconductor module according to the above-described embodiment further includes the coating film interposed at the interface between the upper surface of the first bonding portion and the sealing resin, in which the coating film has a thickness of 0.1 μm or more and 20 μm or less, and the first recess and the second recess are covered with the coating film.

In the semiconductor module according to the above-described embodiment, the plurality of second recesses are arranged in a staggered manner.

In the semiconductor module according to the above-described embodiment, the density of the plurality of second recesses arranged on the outer peripheral side of the first recess is larger than the density of the plurality of second recesses arranged on the inner peripheral side of the first recess.

In the semiconductor module according to the above-described embodiment, the second recess is formed on the bottom surface of the first recess.

In the semiconductor module according to the above-described embodiment, the side surface of the boss and the inner side surface of the first recess have a tapered shape whose diameter decreases downward, and the second recess is formed on the inner side surface of the first recess.

Further, in the semiconductor module according to the above-described embodiment, the metal wiring board has the second bonding portion bonded to the upper surface of another circuit board via the second bonding material, the second bonding portion includes the plate-shaped portion having the upper surface and the lower surface, and comprises the second boss formed on the lower surface of the plate-shaped portion and protruding toward the other circuit board, and the third recess formed at the position corresponding to a position immediately above the second boss on the upper surface of the plate-shaped portion, and the second recess is formed only on the upper surface of the first bonding portion.

In the semiconductor module according to the above-described embodiment, the metal wiring board includes the connecting portion that connects the first bonding portion and the second bonding portion, the first bent portion that connects the first bonding portion and one end of the connecting portion and is bent, and the second bent portion that connects the second bonding portion and the other end of the connecting portion and is bent, and the second recess is formed only on the upper surface of the first bonding portion.

In addition, the method for manufacturing the semiconductor module according to the above-described embodiment is the method for manufacturing the above-described semiconductor module and includes a step of pressing and forming the boss, the first recess, and the second recess in the process of manufacturing the metal wiring board.

As described above, the present invention has the effect of improving the bonding strength between the semiconductor element and the metal wiring board while securing the thickness of the bonding material, and is particularly useful for a semiconductor module for industrial or electrical equipment and a method for manufacturing the semiconductor module.

The present application is based on Japanese Patent Application No. 2021-173308 filed on Oct. 22, 2021. All the contents are included here.

What is claimed is:

1. A semiconductor module, comprising:
a stacked substrate including an insulating plate, and first and second circuit boards arranged on an upper surface of the insulating plate;
a semiconductor element arranged on an upper surface of the first circuit board; and
a metal wiring board having a first bonding portion that is bonded to an upper surface of the semiconductor element via a first bonding material, wherein
the first bonding portion includes a first plate-shaped portion having an upper surface and a lower surface opposite to each other, the first plate-shaped portion having
at the lower surface thereof, a boss protruding toward the semiconductor element, and
at the upper surface thereof, a first recess at a position corresponding to a position immediately above the boss and a plurality of second recesses, and
at the upper surface of the first plate-shaped portion, each of the plurality of second recesses has an opening area smaller than an opening area of the first recess.

2. The semiconductor module according to claim 1, wherein the lower surface of the first bonding portion excluding an area where the boss is formed is flat.

3. The semiconductor module according to claim 2, wherein a surface roughness of the lower surface of the first plate-shaped portion is less than a surface roughness of the upper surface of the first plate-shaped portion.

4. The semiconductor module according to claim 1, wherein at the upper surface of the first plate-shaped portion, the opening area of each of the plurality of second recesses has a size in range of 0.5% to 75% of a size of the opening area of the boss or the first recess.

5. The semiconductor module according to claim 1, wherein in a direction from the upper surface toward the lower surface of the first plate-shaped portion, a depth of each of the plurality of second recesses is less than a depth of the first recess.

6. The semiconductor module according to claim 1, wherein when viewed from a direction orthogonal to the upper surface of the first plate-shaped portion, the boss and the first recess each have a circular shape, and each of the plurality of second recesses has a polygonal shape.

7. The semiconductor module according to claim 1, wherein the upper surface of the first plate-shaped portion has an annular protrusion surrounding a corresponding one of the plurality of second recesses.

8. The semiconductor module according to claim 1, wherein the upper surface of the first plate-shaped portion has a plurality of annular protrusions respectively surrounding respective ones of the plurality of second recesses, the upper surface of the first plate-shaped portion having a flat portion between at least an adjacent two of the plurality of annular protrusions.

9. The semiconductor module according to claim 1, further comprising a sealing resin that seals the stacked substrate, the semiconductor element, and the metal wiring board, wherein
the sealing resin covers an upper surface of the first bonding portion and fills the first recess and the plurality of second recesses.

10. The semiconductor module according to claim 9, further comprising a coating film at an interface between the upper surface of the first bonding portion and the sealing resin, the coating film covering surfaces of the first recess and the plurality of second recesses, wherein
the coating film has a thickness in range of 0.1 μm to 20 μm.

11. The semiconductor module according to claim 1, wherein
the plurality of second recesses are arranged in a staggered manner.

12. The semiconductor module according to claim 1, wherein the plurality of second recesses are arranged so as to surround the first recess from an inner peripheral side of the first recess toward an outer peripheral side of the first recess such that a density of ones of the plurality of second recesses arranged at the outer peripheral side is greater than a density of ones of the plurality of second recesses arranged at the inner peripheral side.

13. The semiconductor module according to claim 1, wherein the plurality of second recesses are each formed on at least a bottom surface of the first recess.

14. The semiconductor module according to claim 13, wherein
an outer side surface of the boss and an inner side surface of the first recess each have a tapered shape having a diameter that decreases downward toward the semiconductor element, and
the plurality of second recesses are formed on the inner side surface and the bottom surface of the first recess.

15. The semiconductor module according to claim 1, wherein
the metal wiring board has a second bonding portion bonded to an upper surface of the second circuit board via a second bonding material,
the second bonding portion includes a second plate-shaped portion having an upper surface and a lower surface opposite to each other, and includes
at the lower surface thereof, a second boss protruding toward the second circuit board, and
at the upper surface thereof, a third recess formed at a position corresponding to a position immediately above the second boss, and
the plurality of second recesses are formed only on the upper surface of the first plate-shaped portion.

16. The semiconductor module according to claim 15, wherein
the metal wiring board includes
a first bent portion that is connected to the first bonding portion and is bent away from the first bonding portion,
a second bent portion that is connected to the second bonding portion and is bent away from the second bonding portion, and
a connecting portion that connects the first bent portion to the second bent portion.

17. A method for manufacturing the semiconductor module according to claim 1, the method comprising
pressing a metal plate to form the boss, the first recess and the plurality of second recesses, thereby to manufacture the metal wiring board.
